(19) United States
(12) Patent Application Publication
(10) Pub. No.: US 2009/0146204 A1
(43) Pub. Date: Jun. 11, 2009

(54) SEMICONDUCTOR DEVICE AND METHOD OF FABRICATING THE SAME

(76) Inventor: Jin-Ha Park, Echeon-si (KR)

Correspondence Address: SHERR & VAUGHN, PLLC, 620 HERNDON PARKWAY, SUITE 200, HERNDON, VA, 20170, US

(21) Appl. No.: 12/330,659

(22) Filed: Dec. 9, 2008

(30) Foreign Application Priority Data
Dec. 10, 2007 (KR) 10-2007-0127355

(51) Int. Cl. H01L 29/78; H01L 21/3205

(52) U.S. Cl. 257/316; 438/593; 257/E29.3; 257/E21.422

(57) ABSTRACT

A semiconductor device includes a first poly layer over a semiconductor substrate, an IPD layer over the first poly layer, a second poly layer over the IPD layer, an oxide layer over a sidewall of the second poly layer, a first insulating layer over a sidewall of the oxide layer, and a second insulating layer over a sidewall of the first insulating layer.

The present application claims priority under 35 U.S.C. 119 to Korean Patent Application No. 10-2007-0127355 (filed on Dec. 10, 2007), which is hereby incorporated by reference in its entirety.

### BACKGROUND

Portable devices such as mobile communication terminals have been extensively used. These portable devices have been manufactured in successively smaller sizes. Thus, there are demands for fabricating semiconductor devices in a smaller size while improving the degree of integration of the semiconductor devices.

### SUMMARY

Embodiments relate to a semiconductor device and a method of fabricating the same, which can improve the reliability and product yield of devices.

A semiconductor device according to an embodiment may include a first poly layer over a semiconductor substrate, an inter poly dielectric layer over the first poly layer, a second poly layer over the inter poly dielectric layer, an oxide layer over a sidewall of the second poly layer, a first insulating layer over a sidewall of the oxide layer, and a second insulating layer over a sidewall of the first insulating layer.

A method of fabricating a semiconductor device according to embodiments includes forming a first poly layer over a substrate, forming an inter poly dielectric layer over the first poly layer, forming a second poly layer over the inter poly dielectric layer, patterning a hard mask over the second poly layer, etching a part of the second poly layer by using the hard mask as an etching mask, forming an oxide layer over the exposed second poly layer, and patterning the second poly layer, the inter poly dielectric layer and the first poly layer by etching the second poly layer, the inter poly dielectric layer and the first poly layer using the hard mask as the etching mask.

A method of fabricating a semiconductor device according to embodiments includes forming a first poly layer over a substrate, forming an inter poly dielectric layer over the first poly layer, forming a second poly layer over the inter poly dielectric layer, patterning a hard mask over the second poly layer, exposing the inter poly dielectric layer by etching the second poly layer using the hard mask as an etching mask, forming an oxide layer over the exposed second poly layer, and patterning the inter poly dielectric layer and the first poly layer by etching the inter poly dielectric layer and the first poly layer using the hard mask as an etching mask.

According to embodiments, the reliability and product yield of devices can be improved.

### DRAWINGS

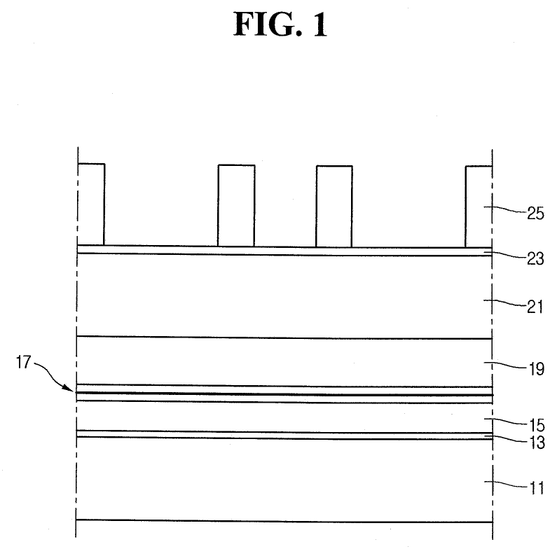

Example FIGS. 1 to 8 are sectional views illustrating a semiconductor device manufacturing method according to embodiments.

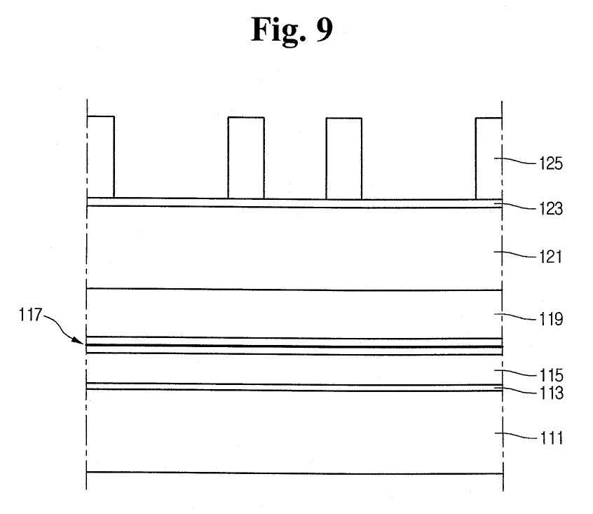

Example FIGS. 9 to 16 are sectional views illustrating a semiconductor device manufacturing method according to embodiments.

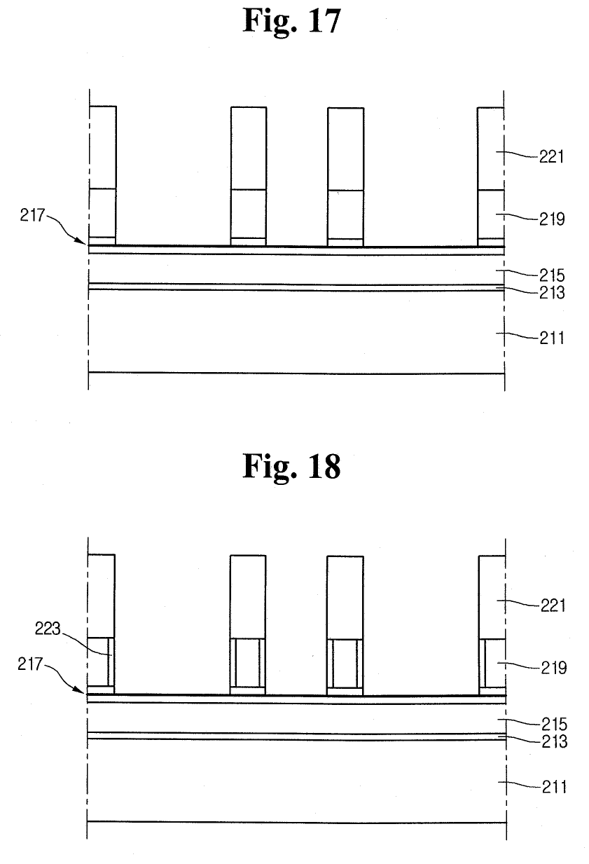

Example FIGS. 17 to 21 are sectional views illustrating a semiconductor device manufacturing method according to embodiments.

### DESCRIPTION

Example FIGS. 1 to 8 are sectional views illustrating the procedure of fabricating a NOR flash using a semiconductor device manufacturing method according to embodiments. As illustrated in example FIG. 1, a tunnel oxide layer 13, a first poly layer 15, an ONO (oxide-nitride-oxide) layer 17, a second poly layer 19 and a hard mask 21 may be laminated over a substrate 11. An anti-reflection layer 23 may be formed over the hard mask 21 and a photoresist layer 25 may be patterned over the anti-reflection layer 23.

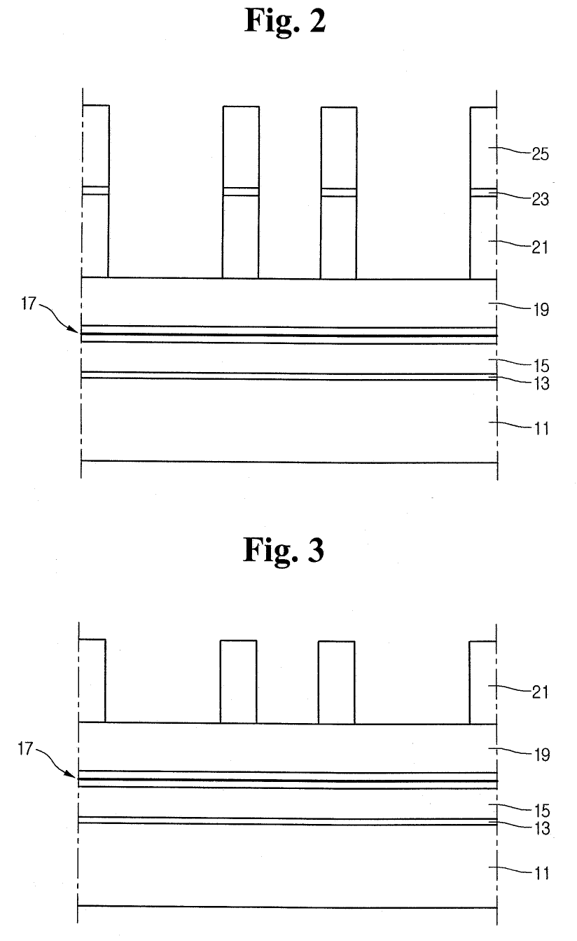

As illustrated in example FIG. 2, the hard mask 21 may be patterned through an etching process to expose the second poly layer 19. As illustrated in example FIG. 3, the photoresist layer 25 and the anti-reflection layer 23 may be removed through an asher process.

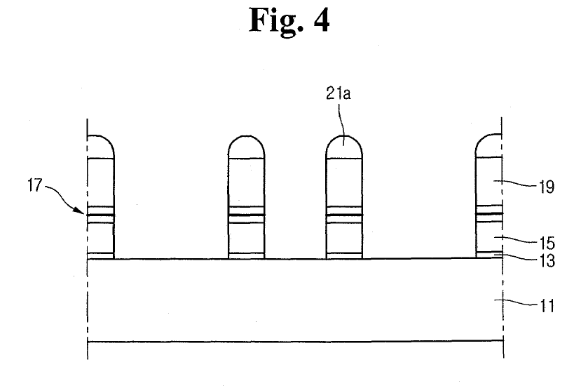

As illustrated in example FIG. 4, the second poly layer 19, the ONO layer 17 and the first poly layer 15 may be etched using the hard mask 21 as an etching mask. The tunnel oxide layer 13 may also be etched. Hard mask pattern 21 a remains over the second poly layer 19.

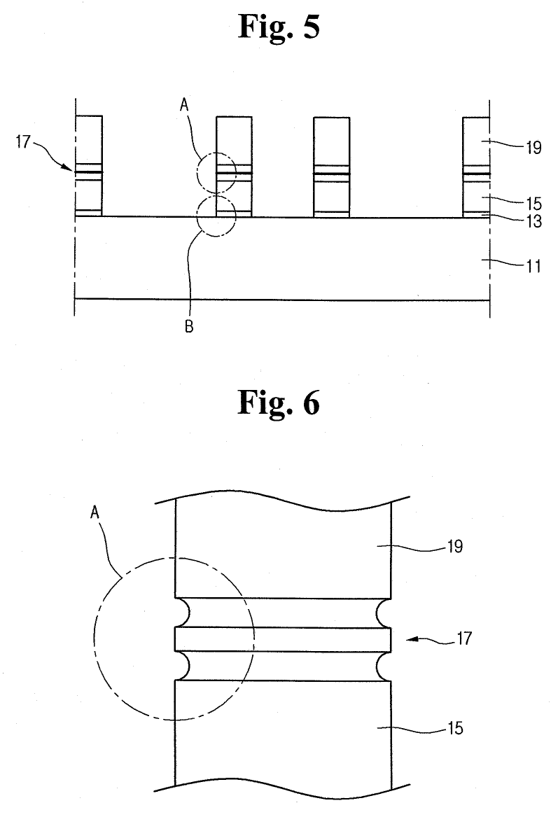

As illustrated in example FIG. 5, a wet etch process may be performed to remove the hard mask pattern 21a. At this point, a part A of the ONO layer 17 and a part B of the tunnel oxide layer 13 may be damaged. Example FIG. 6 is an enlarged sectional view of the part A of the ONO layer 17. The degree of damage to the ONO layer 17 and the tunnel oxide layer 13 may be increased depending on the thickness of the hard mask pattern 21a. Depending on the damage to the ONO layer 17 and the tunnel oxide layer 13, a coupling ratio may be reduced and the efficiency of a flash cell may be degraded.

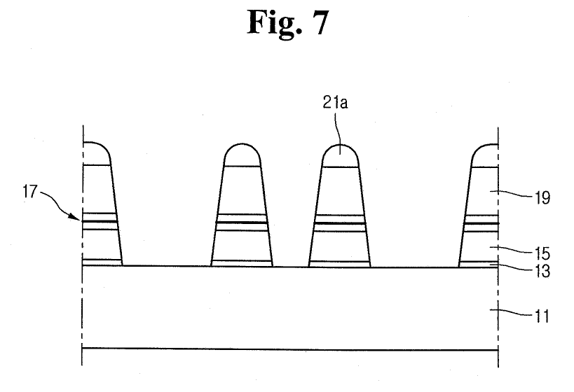

When the thickness of the hard mask pattern 21a is reduced to solve such problems, the second poly layer 19 and the first poly layer 15 may be abnormally etched during the etch process as illustrated in example FIG. 7. This is because the reduced thickness hard mask pattern 21a does not sufficiently cover the second poly layer 19. Thus the outer peripheral portion of an upper portion of the second poly layer 19 is damaged while the wet etch process is being performed.

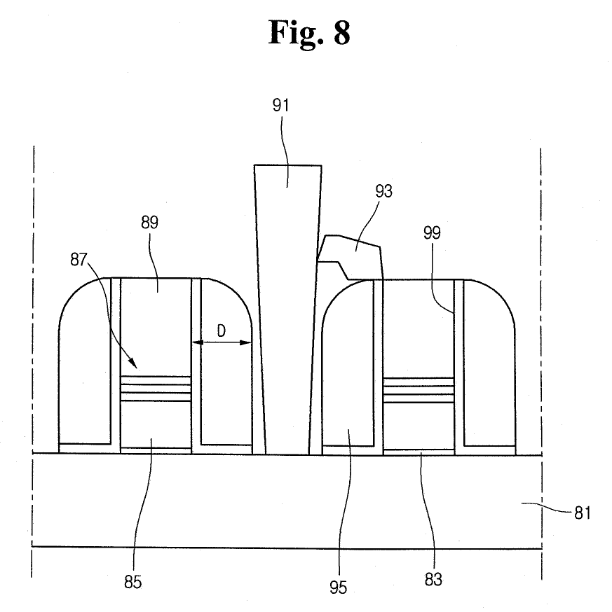

Example FIG. 8 shows an example of a semiconductor device fabricated through the manufacturing procedure as described above. As illustrated in example FIG. 8, a tunnel oxide layer 83, a first poly layer 85, an ONO layer 87 and a second poly layer 89 may be laminated over a semiconductor substrate 81. The first poly layer 85 may serve as a floating gate and the second poly layer 89 may serve as a control gate. A nitride layer 95 may be formed over a sidewall of the second poly layer 89. As the semiconductor device is manufactured in a smaller size, the distance D between the second poly layer 89 and the outer surface of the nitride layer 95 is reduced. For example, as 130 nm technology advances to 90 nm technology, the cell size is reduced by 50%.

With reductions in size, the distance between the second poly layer 89 and a contact 91 becomes an important factor in the semiconductor device. In a 90 nm device, for example, the distance between the second poly layer 89 and a contact 91 is reduced to between about 70 nm to about 90 nm. As this spacing between the second poly layer 89 and the contact 91 is reduced, abnormal operation of a cell may be caused by a bridge. When a defect 93 is generated as illustrated in example FIG. 8, a bridge may be formed between the second poly layer 89 and the contact 91. The defect 93 may include conductive particles which may be generated in the manufacturing procedure.

Example FIGS. 9 to 16 are sectional views illustrating the procedure of fabricating a NOR flash using a semiconductor device manufacturing method according to embodiments. As illustrated in example FIG. 9, a tunnel oxide layer 113, a first poly layer 115, an IPD (inter poly dielectric) layer 117, a second poly layer 119 and a hard mask 121 may be laminated over a substrate 111. The substrate 111 may include a silicon substrate. The IPD layer 117 may include an ONO layer. Then, an anti-reflection layer 123 may be formed over the hard mask 121 and a photoresist layer 125 may be patterned over the anti-reflection layer 123. The hard mask 121 may include an oxide layer.

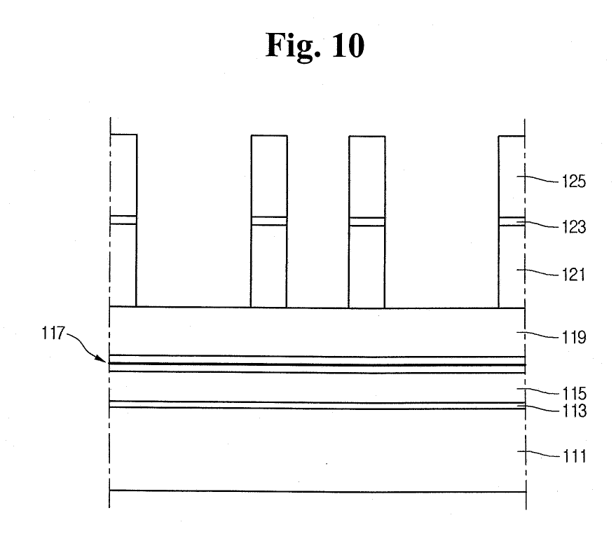

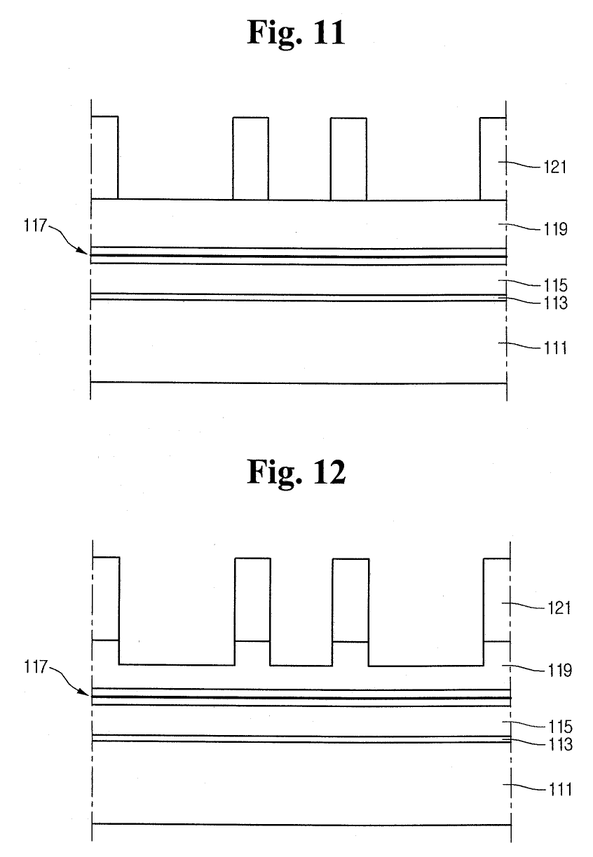

As illustrated in example FIG. 10, the hard mask 121 may be patterned through an etching process to expose the second poly layer 119. As illustrated in example FIG. 11, the photoresist layer 125 and the anti-reflection layer 123 may be removed. For example, the photoresist layer 125 and the anti-reflection layer 123 may be removed through an asher process.

As illustrated in example FIG. 12, a part of the second poly layer 119 may be etched using the hard mask 121 as an etching mask. In particular, the second poly layer 119 might not be completely etched one time and only a part of the second poly layer 119 is etched. The second poly layer 119 may be etched by thickness of ⅓ to ½ of the original thickness thereof.

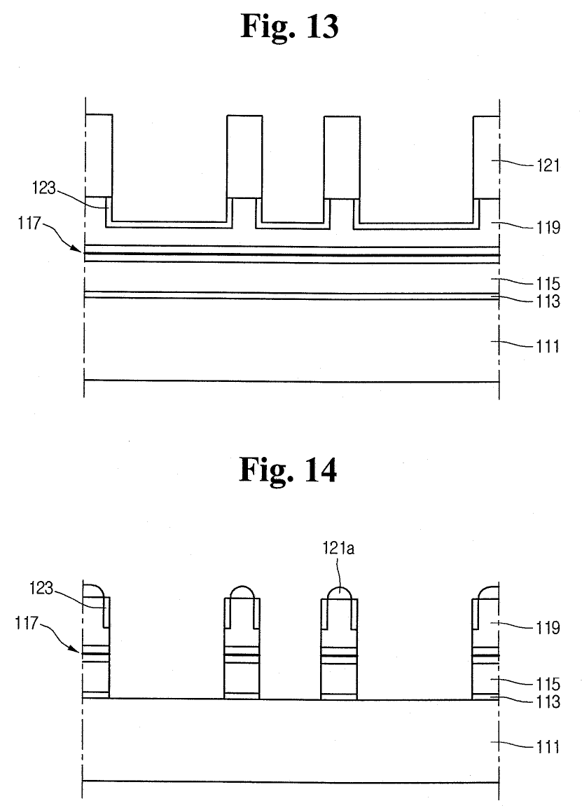

As illustrated in example FIG. 13, an oxide layer 123 may be formed over the second poly layer 119. The oxide layer 123 may be deposited through an LPCVD (low pressure chemical vapor deposition) process, to have a thickness of about 100 Å to about 200 Å.

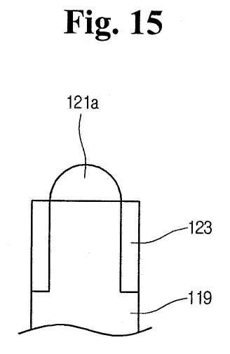

As illustrated in example FIG. 14, the second poly layer 119, the IPD layer 117 and the first poly layer 115 may be etched. The tunnel oxide layer 113 may also be etched. A hard mask pattern 121a exists over the second poly layer 119. As illustrated in example FIG. 15, the hard mask pattern 121a exists over the second poly layer 119, and the oxide layer 123 exists over the outer peripheral portion of an upper portion of the second poly layer 119. A wet etch process may be performed to remove the hard mask pattern 121a.

According to embodiments illustrated in FIGS. 9-16, since the upper surface of the second poly layer 119 can be protected by the oxide layer 123 and the hard mask pattern 121a as illustrated in example FIG. 15, the second poly layer 119 can be prevented from being damaged in the wet etch process. Thus, a degree of freedom can be ensured when the manufacturing process is performed to reduce the thickness of the hard mask pattern 121a. According to embodiments illustrated in FIGS. 9-16, the thickness of the hard mask pattern 121a can be reduced, so that time required for the etching process can be shortened. The IPD layer 117 and the tunnel oxide layer 113 can be efficiently prevented from being damaged. Thus, a stable coupling ratio can be ensured to improve the cell characteristics.

Further, according to embodiments illustrated in FIGS. 9-16, since the oxide layer 123 exists over the upper outer peripheral portion of the second poly layer 119, the hard mask 121 of example FIG. 9 can be thinner and a degree of freedom for design can be ensured as compared with the related art.

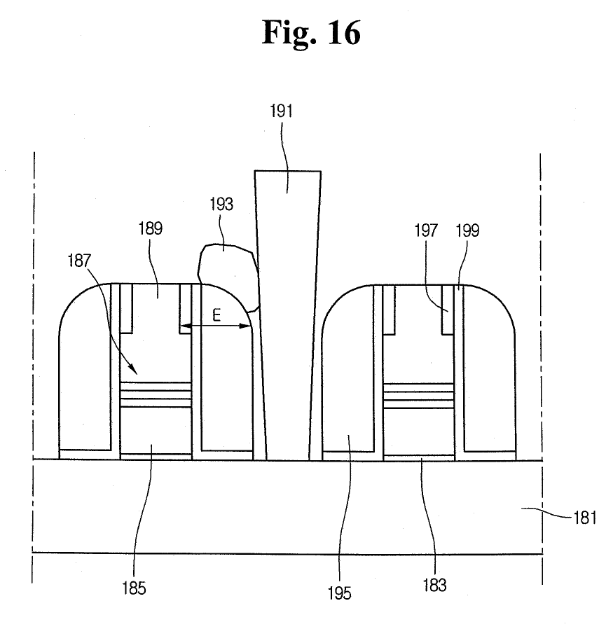

Example FIG. 16 shows an example of a semiconductor device fabricated through the manufacturing procedure as described above. As illustrated in example FIG. 16, a tunnel oxide layer 183, a first poly layer 185, an IPD layer 187 and a second poly layer 189 may be laminated over a semiconductor substrate 181. The first poly layer 185 may serve as a floating gate and the second poly layer 189 may serve as a control gate.

An oxide layer 197 may be formed over the upper sidewall of the second poly layer 189. A first insulating layer 199 may be formed over the sidewall of the oxide layer 197. The first insulating layer 199 may also be formed over the lower sidewall of the second poly layer 189 as well as over the sidewall of the first poly layer 185. A second insulating layer 195 may be formed over the sidewall of the first insulating layer 199. The first insulating layer 199 may include an oxide layer and the second insulating layer 195 may include a nitride layer.

According to the embodiments as described above, the distance E between the second poly layer 89 and the outer surface of the second insulating layer 195 can be efficiently ensured. In particular, the insulating layer can be formed over the upper outer peripheral portion of the second poly layer 189 by the thickness of the oxide layer 197.

Thus, an interval can be stably ensured between the second poly layer 189 and a contact 191 and a bridge can be efficiently prevented. According to the second embodiment, although a defect 193 is generated, the bridge can be prevented from being formed between the second poly layer 189 and the contact 191 and the product yield can be improved. The defect 193 includes conductive particles which may be generated in the manufacturing procedure.

Example FIGS. 17 to 21 are sectional views illustrating a semiconductor device manufacturing method according to embodiments.

The third embodiment is identical to the first and second embodiments, except for a process of etching a second poly layer. The procedure shown in example FIG. 9 can be applied to the third embodiment. According to the third embodiment, a second poly layer 219 is completely etched using a hard mask 221 at a time. The hard mask 221 may include an oxide layer.

As the second poly layer 219 is etched, an IPD layer 217 below the second poly layer 219 may be exposed. The IPD layer 217 may include an ONO layer. When the IPD layer 217 uses the ONO layer, a nitride layer may serve as an etching stop layer.

According to the third embodiment, as illustrated in example FIG. 17, a tunnel oxide layer 213, a first poly layer 215 and an IPD layer 217 are laminated over a substrate 211. Then, the second poly layer 219 over the IPD layer 217 is patterned through an etch process using the patterned hard mask 221. The substrate 211 may include a silicon substrate.

As illustrated in example FIG. 18, an oxide layer 223 may be formed over the second poly layer 219. The oxide layer 223 may have thickness of about 100 Å to about 200 Å through an LPCVD process.

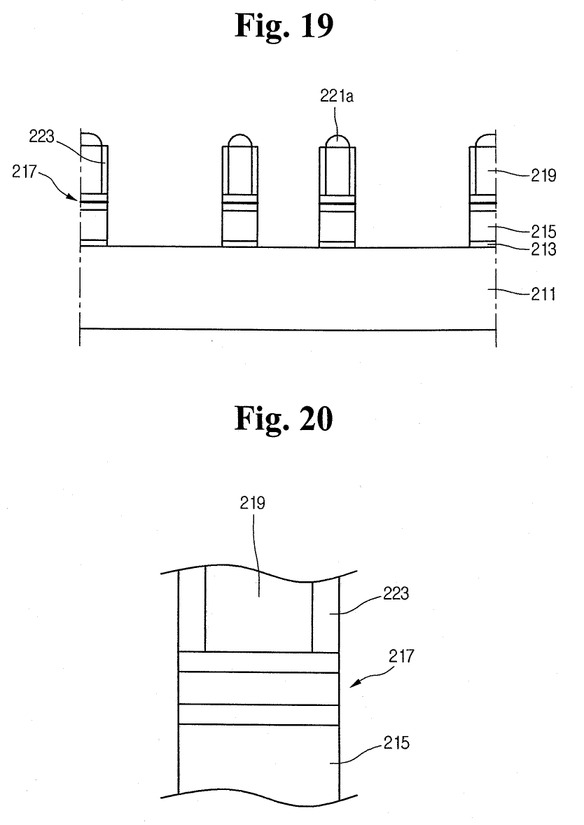

As illustrated in example FIG. 19, the IPD layer 217 and the first poly layer 215 may be etched. At this time, the tunnel oxide layer 213 may also be etched and a hard mask pattern 221a may remain over the second poly layer 219. As illustrated in example FIGS. 19 and 20, the hard mask pattern 221a may remain over the second poly layer 219 and the oxide layer 223 may remain over the sidewall of the second poly layer 219. Then, a wet etch process may be performed to remove the hard mask pattern 221a.

According to embodiments, since the second poly layer 219 can be protected by the oxide layer 223 and the hard mask pattern 221a as illustrated in example FIGS. 19 and 20, damage to the second poly layer 219 can be prevented during the wet etch process. Thus, a degree of freedom can be ensured when the manufacturing process is performed to reduce the thickness of the hard mask pattern 221a. According to embodiments, the thickness of the hard mask pattern 221a can be reduced, so that time required for the etch process can be shortened and the IPD layer 217 and the tunnel oxide layer 213 can be efficiently prevented from being damaged. Thus, a stable coupling ratio can be ensured to improve the cell characteristics.

Further, according to embodiments, since the oxide layer 223 may remain over the sidewall of the second poly layer 219, the hard mask 221 of example FIG. 17 can be thinner and the degree of freedom in design can be ensured as compared with the related art.

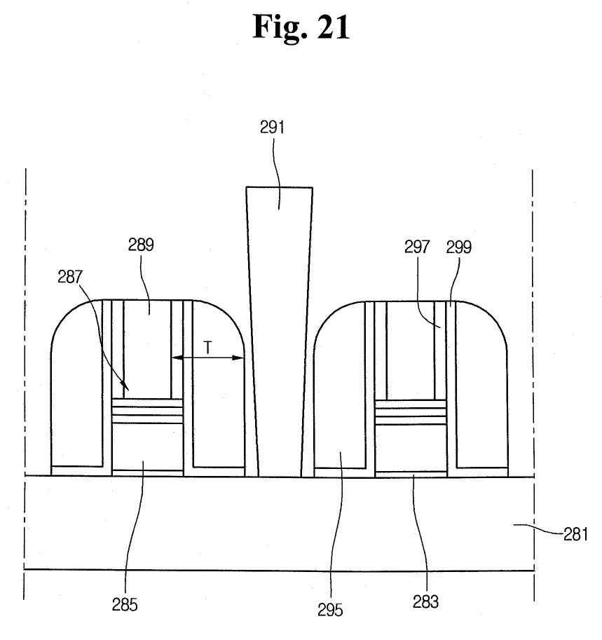

Example FIG. 21 shows an example of a semiconductor device fabricated through the manufacturing procedure as described above. As illustrated in example FIG. 21, a tunnel oxide layer 283, a first poly layer 285, an IPD layer 287 and a second poly layer 289 may be laminated over a semiconductor substrate 281. The first poly layer 285 may serve as a floating gate and the second poly layer 289 may serve as a control gate.

An oxide layer 297 may be formed over the sidewall of the second poly layer 289 and a first insulating layer 299 may be formed over the sidewall of the oxide layer 297. The first insulating layer 299 may also be formed over the sidewall of the oxide layer 297 as well as over the sidewall of the first poly layer 285. A second insulating layer 295 may be formed over the sidewall of the first insulating layer 299. The first insulating layer 299 may include an oxide layer and the second insulating layer 295 may include a nitride layer.

According to embodiments as described above, the distance T between the second poly layer 289 and the outer surface of the second insulating layer 295 can be efficiently ensured. In detail, the insulating layer can be formed over the lateral side of the second poly layer 289 by the thickness of the oxide layer 297.

Thus, an interval can be stably ensured between the second poly layer 289 and a contact 291, and a bridge can be efficiently prevented. According to embodiments, although a defect is generated, the bridge can be prevented from being formed between the second poly layer 289 and the contact 291, and the product yield can be improved. The defect may include conductive particles which may be generated in the manufacturing procedure.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first poly layer over a semiconductor substrate;
an inter poly dielectric layer over the first poly layer;
a second poly layer over the inter poly dielectric layer;
an oxide layer over a sidewall of the second poly layer;
a first insulating layer over a sidewall of the oxide layer; and
a second insulating layer over a sidewall of the first insulating layer.

2. The apparatus of claim 1, wherein the first poly layer serves as a floating gate.

3. The apparatus of claim 1, wherein the second poly layer serves as a control gate.

4. The apparatus of claim 1, wherein the oxide layer is formed over an upper sidewall of the second poly layer.

5. The apparatus of claim 1, wherein the oxide layer is formed over an entire sidewall of the second poly layer.

6. The apparatus of claim 1, wherein the first insulating layer includes an oxide layer.

7. The apparatus of claim 1, wherein the second insulating layer includes a nitride layer.

8. The apparatus of claim 1, wherein the inter poly dielectric layer includes an oxide-nitride-oxide layer.

9. A method comprising:
forming a first poly layer over a substrate;
forming an inter poly dielectric layer over the first poly layer;
forming a second poly layer over the inter poly dielectric layer;
patterning a hard mask over the second poly layer;
etching a part of the second poly layer by using the hard mask as an etching mask;
forming an oxide layer over the exposed second poly layer; and
patterning the second poly layer, the inter poly dielectric layer and the first poly layer by etching the second poly layer, the inter poly dielectric layer and the first poly layer using the hard mask as the etching mask.

10. The method of claim 9, including forming first and second insulating layers over sidewalls of the first and second patterned poly layers.

11. The method of claim 10, wherein the first insulating layer includes an oxide layer.

12. The method of claim 10, wherein the second insulating layer includes a nitride layer.

13. The method of claim 9, wherein the first poly layer serves as a floating gate and the second poly layer serves as a control gate.

14. The method of claim 9, wherein the inter poly dielectric layer includes an oxide-nitride-oxide layer.

15. A method comprising:
forming a first poly layer over a substrate;
forming an inter poly dielectric layer over the first poly layer;
forming a second poly layer over the inter poly dielectric layer;
patterning a hard mask over the second poly layer;
exposing the inter poly dielectric layer by etching the second poly layer using the hard mask as an etching mask;
forming an oxide layer over the exposed second poly layer; and
patterning the inter poly dielectric layer and the first poly layer by etching the inter poly dielectric layer and the first poly layer using the hard mask as an etching mask.

16. The method of claim 15, including forming first and second insulating layers over sidewalls of the first and second patterned poly layers.

17. The method of claim 16, wherein the first insulating layer includes an oxide layer.

18. The method of claim 16, wherein the second insulating layer includes a nitride layer.

19. The method of claim 15, wherein the first poly layer serves as a floating gate and the second poly layer serves as a control gate.

20. The method of claim 15, wherein the inter poly dielectric layer includes an oxide-nitride-oxide layer.
